(19) United States
(12) Patent Application Publication
(10) Pub. No.: US 2012/0326156 A1
(43) Pub. Date: Dec. 27, 2012

(54) Organic light-emitting display apparatus and method of manufacturing organic light-emitting display apparatus

(76) Inventors: Jong-Hyun Choi, Yongin-City (KR); Jae-Beom Choi, Yongin-City (KR)

(21) Appl. No.: 13/200,750

(22) Filed: Sep. 30, 2011

(30) Foreign Application Priority Data
Jun. 27, 2011 (KR) 10-2011-0062490

(51) Int. Cl. H01L 29/786; H01L 33/08

(52) U.S. Cl. 257/71; 438/34; 257/E29.273; 257/E33.053

(57) ABSTRACT

An organic light-emitting display apparatus includes a substrate, a thin-film transistor (TFT) on the substrate, the TFT including an active layer, a gate electrode, a source electrode, and a drain electrode, a first insulating film between the gate electrode and the source electrode and between the gate electrode and the drain electrode, a second insulating film between the first insulating film and the source electrode and between the first insulating film and the drain electrode, the second insulating film including an opening, a first electrode between the first insulating film and the second insulating film, the first electrode including a region corresponding to the opening of the second insulating film, an intermediate layer including an organic light-emitting layer, and a second electrode on the intermediate layer.

### CROSS-REFERENCE TO RELATED PATENT APPLICATION

This application claims the benefit of Korean Patent Application No. 10-2011-0062490, filed on Jun. 27, 2011, in the Korean Intellectual Property Office, the disclosure of which is incorporated herein in its entirety by reference.

### BACKGROUND

1. Field

Embodiments relate to an organic light-emitting display apparatus and a method of manufacturing the organic light-emitting display apparatus, and more particularly, to an organic light-emitting display apparatus with easily increased image quality and a method of manufacturing the organic light-emitting display apparatus.

2. Description of the Related Art

Recently, display apparatuses have been replaced by portable thin-film flat panel display apparatuses. Of the thin-film flat panel display apparatuses, organic light-emitting display apparatuses are emissive type display apparatuses that are considered to be next-generation display apparatuses due to their large viewing angles, high contrast, and short response times.

### SUMMARY

According to an embodiment, there is provided an organic light-emitting display apparatus including a substrate, a thin-film transistor (TFT) on the substrate, the TFT including an active layer, a gate electrode, a source electrode, and a drain electrode, a first insulating film between the gate electrode and the source electrode and between the gate electrode and the drain electrode, a second insulating film between the first insulating film and the source electrode and between the first insulating film and the drain electrode, the second insulating film including an opening, a first electrode between the first insulating film and the second insulating film, the first electrode including a region corresponding to the opening of the second insulating film, an intermediate layer including an organic light-emitting layer, and a second electrode on the intermediate layer.

The organic light-emitting display apparatus may further include a protective layer disposed on the first electrode such that the protective layer does not overlap with the opening of the second insulating film.

The protective layer may include at least one material selected from Mo, Ti, Cu, and Ag.

The second insulating film may further include a via-hole that overlaps with the protective layer. One of the source electrode and the drain electrode may be connected to the protective layer through the via-hole.

The organic light-emitting display apparatus may further include a capacitor on the substrate, wherein the capacitor includes a first capacitor electrode that is formed of a same material as the gate electrode and is formed on a same layer as the gate electrode, and a second capacitor electrode that is formed of a same material as the first electrode between the first insulating film and the second insulating film.

The organic light-emitting display apparatus may further include a cover layer on the second capacitor electrode.

The cover layer may include at least one material selected from Mo, Ti, Cu, and Ag.

The first electrode may include a transparent conductive material.

The transparent conductive material may be at least one of indium tin oxide (ITO), indium zinc oxide (IZO), zinc oxide (ZnO), indium oxide (In₂O₃), indium gallium oxide (IGO), and aluminum zinc oxide (AZO).

The first electrode may include a first transparent conductive material layer sequentially stacked on an upper surface of a semi-transparent metal layer.

The first electrode may further include a second transparent conductive material layer under the semi-transparent metal layer.

The semi-transparent metal layer may include Ag.

The intermediate layer may be disposed to correspond to the opening, and the opening may be formed not to overlap with the TFT but to be separate from the TFT.

According to an embodiment, there is provided a method of manufacturing an organic light-emitting display apparatus, the method including forming a thin-film transistor (TFT) that includes an active layer, a gate electrode, a source electrode, and a drain electrode on a substrate, forming a first insulating film between the gate electrode and the source electrode and between the gate electrode and the drain electrode, forming a second insulating film having an opening on the first insulating film, forming a first electrode between the first insulating film and the second insulating film, such that the first electrode includes a region corresponding to the opening, forming an intermediate layer having an organic light-emitting layer on the first electrode, and forming a second electrode on the intermediate layer.

The method may further include forming a protective layer on the first electrode such that the protective layer does not overlap with the opening.

The source electrode, the drain electrode and the protective layer may be formed by patterning. The forming of the protective layer may include forming a conductive material layer on the first electrode in a same pattern as the first electrode and patterning the protective layer by removing a region of the conductive material layer that overlaps with the opening, when the source electrode and the drain electrode are removed.

The forming of the protective layer may include forming a conductive material layer using a same material used for the protective layer on the first electrode in a same pattern as the first electrode, forming the second insulating film on the conductive material layer to form a resultant structure, forming a conductive layer for forming the source electrode and the drain electrode on the second insulating film, the conductive layer for forming the source electrode and the drain electrode including a region corresponding to the opening without having a pattern, and patterning the conductive layer for forming the source electrode and the drain electrode to form the source electrode and the drain electrode. In the patterning of the source electrode and the drain electrode, a region of the conductive layer for forming the source electrode and the drain electrode that contacts the opening may be removed, and a region of the conductive material layer that overlaps with the opening may be removed.

The method may further include washing the resultant structure using a washing solution before the forming of the conductive layer for forming the source electrode and the drain electrode.

### BRIEF DESCRIPTION OF THE DRAWINGS

The above and other features will become more apparent by describing in detail exemplary embodiments thereof with reference to the attached drawings in which:

FIG. 1 is a schematic cross-sectional view of an organic light-emitting display apparatus according to an embodiment, and

FIGS. 2A through 2H are cross-sectional views sequentially showing a method of manufacturing an organic light-emitting display apparatus, according to an embodiment.

### DETAILED DESCRIPTION

Embodiments will now be described more fully with reference to the accompanying drawings in which exemplary embodiments are shown. In the drawings, the thicknesses of layers and regions are exaggerated for clarity, and like reference numerals refer to like elements.

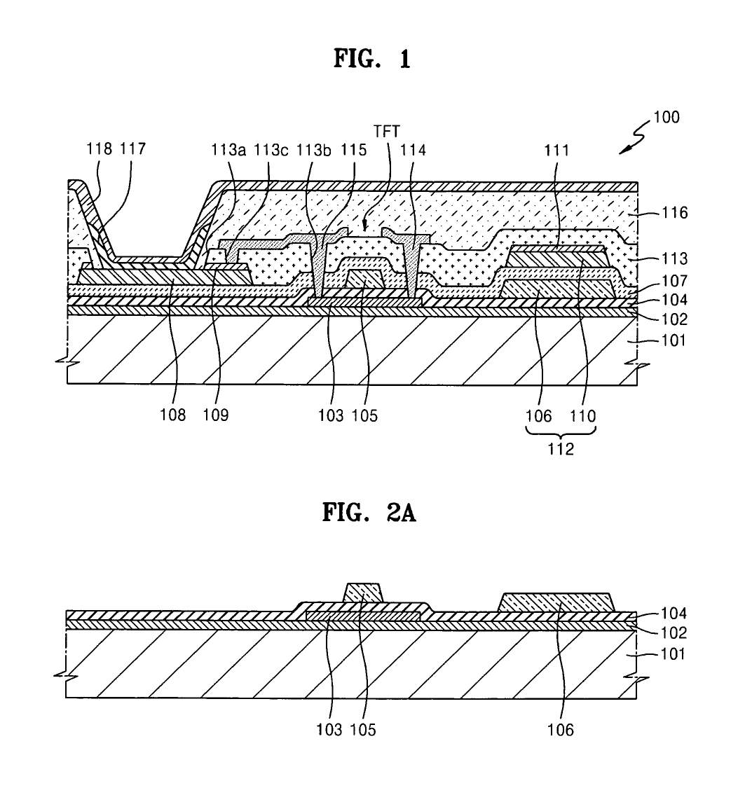

FIG. 1 is a schematic cross-sectional view of an organic light-emitting display apparatus 100 according to an embodiment.

Referring to FIG. 1, the organic light-emitting display apparatus 100 may include a substrate 101, a thin-film transistor TFT, a first electrode 108, an intermediate layer 117, a second electrode 118, a first insulating film 107, a second insulating film 113, and a capacitor 112.

The thin-film transistor TFT may include an active layer 103, a gate electrode 105, a source electrode 114, and a drain electrode 115. The capacitor 112 may include a first capacitor electrode 106 and a second capacitor electrode 110.

The configuration of each member is described as follows.

The substrate 101 may be formed of a transparent glass material that uses SiO₂ as a main component. The substrate 101 may also be formed of other materials such as a transparent plastic material. The transparent plastic material used to form the substrate 101 may be one of various organic materials.

A buffer layer 102 may be formed on the substrate 101. The buffer layer 102 may include SiO₂ or SiNₓ. The buffer layer 102 may provide a planarized surface on the substrate 101 and may prevent moisture and foreign materials from penetrating into the substrate 101.

The active layer 103 may be formed on the buffer layer 102. The buffer layer 102 may be formed of a semiconductor material, for example, an amorphous silicon material or a polycrystalline silicon material.

A gate insulating film 104 may be formed on the buffer layer 102 to cover the active layer 103.

The gate electrode 105 and the first capacitor electrode 106 may be formed on the gate insulating film 104. The gate electrode 105 may be formed of a metal or an alloy of metals such as Mo, MoW, or Al, for example. The first capacitor electrode 106 may be formed of the same material used to form the gate electrode 105.

The first insulating film 107 may be formed on the gate insulating film 104 to cover the gate electrode 105 and the first capacitor electrode 106. The first insulating film 107 may include various insulating materials such as organic materials or inorganic materials.

The first electrode 108 and the second capacitor electrode 110 may be formed on the first insulating film 107. The first electrode 108 may be formed of various materials.

The first electrode 108 may include a transparent conductive material, for example, at least one material selected from indium tin oxide (ITO), indium zinc oxide (IZO), zinc oxide (ZnO), indium oxide (In₂O₃), indium gallium oxide (IGO), and aluminum zinc oxide (AZO).

Also, the first electrode 108 may have a bi-layer structure instead of a single layer structure. For example, a transparent conductive material layer may be formed on a semi-transparent metal layer formed of a metal such as silver Ag. In other words, the first electrode 108 may have a stack structure of ITO/Ag. Also, instead of ITO, a material selected from IZO, ZnO, In₂O₃, IGO, and AZO may be used.

Also, the first electrode 108 may have a three-layer structure, that is, a stack layer of ITO/Ag/ITO. Also, instead of ITO, a material selected from IZO, ZnO, In₂O₃, IGO, and AZO may be used.

The first electrode 108 may be formed as a semi-transparent metal layer so that visible light generated from the intermediate layer 117 may resonate between the first electrode 108 and the second electrode 118.

The second capacitor electrode 110 may be formed of the same material used to form the first electrode 108. In other words, the second capacitor electrode 110 may also include a transparent conductive material, like the first electrode 108, and may be formed in a bi-layer structure or a triple-layer structure. In FIG. 1, the second capacitor electrode 110 may have a size similar to that of the first capacitor electrode 106. However, the second capacitor electrode 110 may have other sizes, and the second capacitor electrode 110 may be formed smaller than the first capacitor electrode 106.

A protective layer 109 may be formed on the first electrode 108. The protective layer 109 may be formed to correspond to a predetermined region of the first electrode 108, and more specifically, the protective layer 109 may be formed not to overlap with an opening 113a of the second insulating film 113.

The protective layer 109 may be formed of at least a transparent conductive material selected from the group consisting of Mo, Ti, Cu, and Ag.

A cover layer 111 may be formed on the second capacitor electrode 110. The cover layer 111 may be formed to have the same pattern as the second capacitor electrode 110, and may be formed of the same material used to form the protective layer 109.

The second insulating film 113 may be formed on the first insulating film 107, the protective layer 109, and the cover layer 111. The second insulating film 113 may be formed of various insulating materials such as organic or inorganic materials. The second insulating film 113 may be formed of the same or different material used to form the first insulating film 107.

The second insulating film 113 may include the opening 113a, a contact hole 113b, and a via-hole 113c. The opening 113a may be formed to expose a predetermined region of the first electrode 108. Also, the opening 113a may be formed not to overlap with the protective layer 109. More specifically, the protective layer 109 may be formed adjacent to the opening 113a.

The opening 113a may not overlap with the thin-film transistor TFT, and also may be formed not to overlap with the capacitor 112. In this way, visible light generated from the intermediate layer 117 that is formed to correspond to the opening 113a may be transmitted towards the substrate 101 without interference by the thin-film transistor TFT and the capacitor 112.

The via-hole 113c may be formed to correspond to the protective layer 109.

The source electrode 114 and the drain electrode 115 may be formed on the second insulating film 113 to be electrically connected to the active layer 103. Specifically, the source electrode 114 and the drain electrode 115 may be formed to be electrically connected to the active layer 103 through the contact hole 113b.

One of the source electrode 114 and the drain electrode 115 may be electrically connected to the first electrode 108. In FIG. 1, it is depicted that the drain electrode 115 is electrically connected to the first electrode 108. Specifically, the drain electrode 115 contacts the protective layer 109 through the via-hole 113c. Because the protective layer 109 may be formed of a conductive material, the drain electrode 115 may be electrically connected to the first electrode 108.

The source electrode 114 and the drain electrode 115 may be formed of various materials, for example, a metal selected from Au, Pd, Pt, Ni, Rh, Ru, Ir, Os, Al, Mo, Nd, Mo, W, and an alloy of at least two of these metals.

A pixel-defining film 116 may be formed on the second insulating film 113 to cover the thin-film transistor and the capacitor 112. The pixel-defining film 116 may be formed to expose a predetermined region of an upper surface of the first electrode 108.

The intermediate layer 117 may be formed to contact the exposed region of the upper surface of the first electrode 108. The intermediate layer 117 may include an organic light-emitting layer (not shown).

The second electrode 118 may be formed on the intermediate layer 117. The second electrode 118 may include various conductive materials, for example, reflective materials. In this way, visible light generated from the intermediate layer 117 may be reflected by the second electrode 118, and a resonance effect of visible light may be generated between the first electrode 108 and the second electrode 118.

In other words, visible light generated from the intermediate layer 117 may be transmitted towards the first electrode 108 after resonating between the first electrode 108 and the second electrode 118. In this way, an optical efficiency of the organic light-emitting display apparatus 100 may be increased.

Visible light is generated from the intermediate layer 117 when a voltage is applied to the intermediate layer 117 through the first electrode 108 and the second electrode 118.

A sealing member (not shown) may be disposed on the second electrode 118. The sealing member (not shown) may be formed to protect the intermediate layer 117 or other layers from the penetration of external moisture or oxygen using a transparent material. The sealing member (not shown) may be formed of various materials, for example, glass, plastic, an organic material, an inorganic material, or may be formed as an overlapping structure of an organic material and an inorganic material.

In the organic light-emitting display apparatus 100 according to the current embodiment, the first insulating film 107 and the second insulating film 113 may be formed between the gate electrode 105, the source electrode 114, and the drain electrode 115. Also, the first electrode 108 may be formed between the first insulating film 107 and the second insulating film 113. In this way, the first electrode 108 is not formed on the same layer as the gate electrode 105, the source electrode 114, and the drain electrode 115. Accordingly, the first electrode 108 may be prevented from being contaminated and may be protected from a failure that may occur when the gate electrode 105, the source electrode 114, and the drain electrode 115 are formed. As a result, the electrical characteristics of the first electrode 108 may be increased, and thus, the image quality of the organic light-emitting display apparatus 100 may be increased.

Also, the protective layer 109 formed on the first electrode 108 may effectively protect an upper surface of the first electrode 108, and thus, a reduction in electrical characteristics of the connection between the first electrode 108 and the drain electrode 115 may be prevented.

The first capacitor electrode 106 of the capacitor 112 may be formed on the same layer as the gate electrode 105 using the same material used to form the gate electrode 105. The second capacitor electrode 110 may be formed on the same layer as the first electrode 108 using the same material used to form the first electrode 108. Therefore, the capacitor 112 may be readily formed, and the thickness of the organic light-emitting display apparatus 100 may not be increased. Also, only the first insulating film 107 may be formed between the first capacitor electrode 106 and the second capacitor electrode 110 to reduce a distance between the first capacitor electrode 106 and the second capacitor electrode 110, thereby increasing an electrical capacity of the capacitor 112.

The durability of the second capacitor electrode 110 may be increased by disposing the cover layer 111 on the second capacitor electrode 110. Also, the electrical capacity of the capacitor 112 may be increased if the cover layer 111 is formed of a conductive material.

Also, the first electrode 108 may be formed as a semi-transparent metal layer so that visible light generated from the intermediate layer 117 resonates between the first electrode 108 and the second electrode 118. Therefore, optical efficiency of the organic light-emitting display apparatus 100 may be increased, and thus, the image quality of the organic light-emitting display apparatus 100 may be increased.

The drain electrode 115 that contacts the protective layer 109 and the first electrode 108 may be electrically connected to each other through the protective layer 109. If the protective layer 109 is formed of a metal having high electrical conductivity and high durability, such as Mo, Ti, Cu, and Ag, a contact resistance between the drain electrode 115 and the protective layer 109 may be reduced and the combining durability between the drain electrode 115 and the protective layer 109 may also be increased.

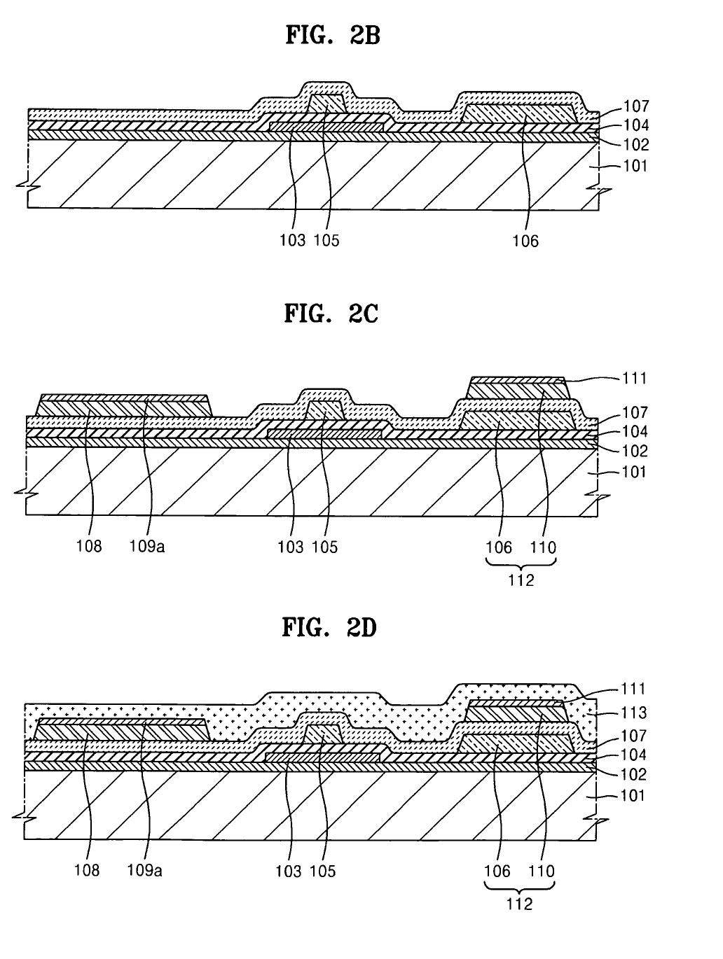

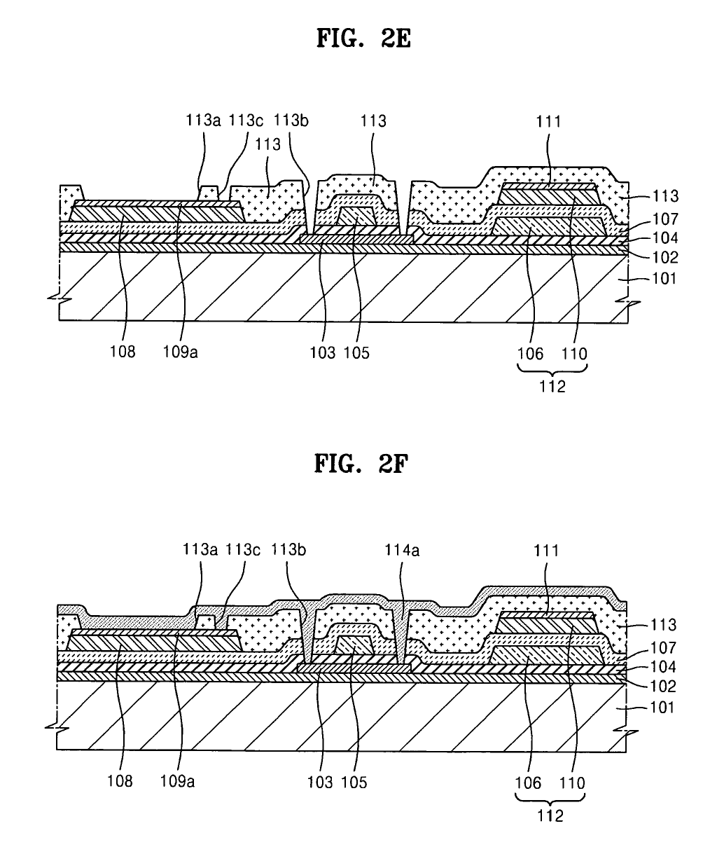

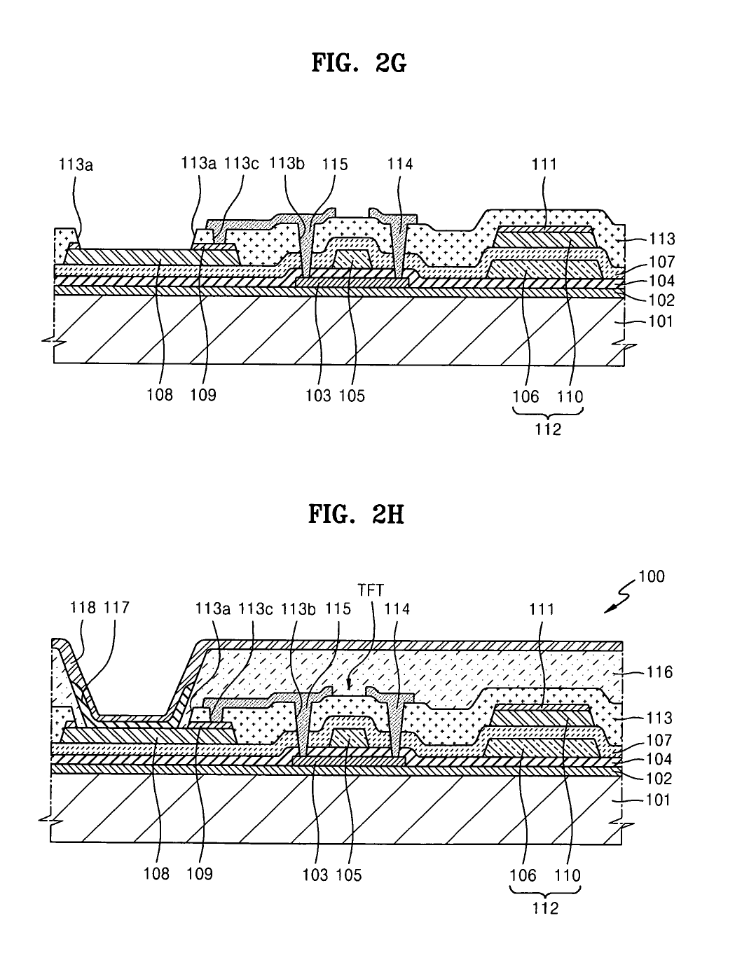

FIGS. 2A through 2H are cross-sectional views sequentially showing a method of manufacturing an organic light-emitting display apparatus, according to an embodiment. More specifically, FIGS. 2A through 2H are cross-sectional views showing a method of manufacturing the organic light-emitting display apparatus 100 of FIG. 1. For convenience of explanation, detailed configurations of each of the elements described in the previous embodiment will not be repeated.

Referring to FIG. 2A, the buffer layer 102, the active layer 103, the gate insulating film 104, the gate electrode 105, and the first capacitor electrode 106 may be formed on the substrate 101.

More specifically, the buffer layer 102 may be formed on the substrate 101, the active layer 103 may be formed on the buffer layer 102, the gate insulating film 104 may be formed on the buffer layer 102 to cover the active layer 103, and the gate electrode 105 and the first capacitor electrode 106 may be formed on the gate insulating film 104 using the same material. The gate electrode 105 and the first capacitor electrode 106 may be simultaneously patterned.

Referring to FIG. 2B, the first insulating film 107 may be formed. More specifically, the first insulating film 107 may be formed on the gate insulating film 104 to cover the gate electrode 105 and the first capacitor electrode 106.

Referring to FIG. 2C, the first electrode 108, a conductive material layer 109a, the second capacitor electrode 110, and the cover layer 111 may be formed on the first insulating film 107.

The conductive material layer 109a may be formed on the first electrode 108 in the same pattern as the first electrode 108. The conductive material layer 109a may include at least one of Mo, Ti, Cu, and Ag so that a surface of the conductive material layer 109a may not be damaged by a washing solution for the active layer 103 such as a hydrofluoric acid (HF) solution or a buffered oxide etching (BOE) solution in a subsequent process.

The cover layer 111 may be formed on the second capacitor electrode 110 in the same pattern as the second capacitor electrode.

The first electrode 108 may be formed of the same material used to form the second capacitor electrode 110. The conductive material layer 109a may be formed of the material used to form the cover layer 111.

For convenience of process, the first electrode 108, the conductive material layer 109a, the second capacitor electrode 110, and the cover layer 111 may be simultaneously patterned using one mask.

Referring to FIG. 2D, the second insulating film 113 may be formed on the first insulating film 107 to cover the first electrode 108, the conductive material layer 109a, the second capacitor electrode 110, and the cover layer 111. The second insulating film 113 may be formed of various materials and may be formed of the same or different material used to form the first insulating film 107.

Referring to FIG. 2E, the opening 113a, the contact hole 113b, and the via-hole 113c may be formed in the second insulating film 113.

The opening 113a and the via-hole 113c may be formed to correspond to the conductive material layer 109a, and the contact hole 113b may be formed to correspond to the active layer 103. At this point, the contact hole 113b may extend to the active layer 103 through the first insulating film 107 and the gate insulating film 104.

After forming the opening 113a, the contact hole 113b, and the via-hole 113c, a washing process may be performed using a washing solution such as an HF solution or a BOE solution. The washing process may increase a contact characteristic between the active layer 103 and the source electrode 114 and the drain electrode 115 by washing the surface of the active layer 103 exposed through the contact hole 113b. At this point, if the first electrode 108 includes an exposed transparent conductive material, the transparent conductive material may be damaged by the washing solution. However, in the current embodiment, the damage to the first electrode 108 may be prevented during a washing process if the conductive material layer 109a is formed on the first electrode 108.

Referring to FIG. 2F, a conductive layer 114a for forming an electrode, specifically, for forming the source electrode 114 and the drain electrode 115, may be formed. The conductive layer 114a may be formed without having a pattern and may be formed to correspond to the opening 113a, the contact hole 113b, and the via-hole 113c.

Referring to FIG. 2G, the source electrode 114 and the drain electrode 115 may be formed by patterning the conductive layer 114a. At this point, the conductive layer 114a corresponding to the opening 113a of the second insulating film 113 may be removed, and a portion of the conductive material layer 109a may be also removed together with the conductive layer 114a corresponding to the opening 113a to form the protective layer 109. At this point, damage to the first electrode 108 may be prevented while the conductive material layer 109a is partially etched.

Referring to FIG. 2H, the manufacture of the organic light-emitting display apparatus 100 may be completed by forming the intermediate layer 117 and the second electrode 118.

More specifically, the pixel-defining film 116 may be formed on the second insulating film 113to cover the thin-film transistor TFT and the capacitor 112. The pixel-defining film 116 may be formed to expose a predetermined region of the upper surface of the first electrode 108, and the intermediate layer 117 may be formed on the exposed portion of the first electrode 108.

The second electrode 118 may be formed on the intermediate layer 117. The second electrode 118 may also be formed on the pixel-defining film 116 without having a pattern.

Visible light is generated from an organic light-emitting layer of the intermediate layer 117 when a voltage is applied to the intermediate layer 117 through the first electrode 108 and the second electrode 118.

A sealing member (not shown) may be disposed on the second electrode 118.

In the organic light-emitting display apparatus 100 according to the current embodiment, the first insulating film 107 and the second insulating film 113 may be formed before forming the source electrode 114 and the drain electrode 115 after forming the gate electrode 105 and the first capacitor electrode 106. Also, the first electrode 108 may be formed before forming the second insulating film 113 after forming the first insulating film 107. In this way, the first electrode 108 is not formed on the same layer as the gate electrode 105, the source electrode 114, and the drain electrode 115, and contamination or damage to the first electrode 108 may be prevented when the gate electrode 105, the source electrode 114, and the drain electrode 115 are patterned.

Also, in the current embodiment, the conductive material layer 109a may be formed on the first electrode 108 to prevent the first electrode 108 from being damaged by a washing solution that is used in a washing process, which may be performed before forming the source electrode 114 and the drain electrode 115 to increase surface characteristics of the active layer 103 that corresponds to the contact hole 113b.

Also, the conductive material layer 109a may remain until the patterning of the source electrode 114 and the drain electrode 115 to prevent the first electrode 108 from being damaged during an etching process for patterning the source electrode 114 and the drain electrode 115.

Also, the first capacitor electrode 106 of the capacitor 112 may be formed of the same material used to form the gate electrode 105. The second capacitor electrode 110 may be formed of the same material used to form the first electrode 108. Therefore, the capacitor 112 may be readily formed without using an additional mask.

Only the first insulating film 107 may be formed between the first capacitor electrode 106 and the second capacitor electrode 110 to reduce a distance between the first capacitor electrode 106 and the second capacitor electrode 110, thereby increasing an electrical capacity of the capacitor 112.

By way of summation and review, a typical organic light-emitting display apparatus includes an intermediate layer, a first electrode, and a second electrode. The intermediate layer includes an organic light-emitting layer, and when a voltage is applied to the first electrode and the second electrode, the organic light-emitting layer generates visible light.

Forming the first electrode under the intermediate layer may be difficult. Accordingly, it may be difficult to improve the electrical and physical characteristics of the first electrode; and as a result, it may be difficult to improve the image quality of the organic light-emitting display apparatus. Embodiments described herein may provide an organic light-emitting display apparatus a method of manufacturing the organic light-emitting display apparatus such that an image quality may be easily increased.

While the embodiments have been particularly shown and described with reference to exemplary embodiments thereof, it will be understood by those of ordinary skill in the art that various changes in form and details may be made therein without departing from the spirit and scope thereof as defined by the following claims.

What is claimed is:

1. An organic light-emitting display apparatus comprising:
a substrate;
a thin-film transistor (TFT) on the substrate, the TFT including an active layer, a gate electrode, a source electrode, and a drain electrode;
a first insulating film between the gate electrode and the source electrode and between the gate electrode and the drain electrode;
a second insulating film between the first insulating film and the source electrode and between the first insulating film and the drain electrode, the second insulating film including an opening;
a first electrode between the first insulating film and the second insulating film, the first electrode including a region corresponding to the opening of the second insulating film;
an intermediate layer including an organic light-emitting layer; and
a second electrode on the intermediate layer.

2. The organic light-emitting display apparatus of claim 1, further comprising a protective layer disposed on the first electrode such that the protective layer does not overlap with the opening of the second insulating film.

3. The organic light-emitting display apparatus of claim 2, wherein the protective layer includes at least one material selected from Mo, Ti, Cu, and Ag.

4. The organic light-emitting display apparatus of claim 2, wherein:
the second insulating film further includes a via-hole that overlaps with the protective layer, and
one of the source electrode and the drain electrode is connected to the protective layer through the via-hole.

5. The organic light-emitting display apparatus of claim 1, further comprising a capacitor on the substrate, wherein the capacitor includes a first capacitor electrode that is formed of a same material as the gate electrode and is formed on a same layer as the gate electrode; and a second capacitor electrode that is formed of a same material as the first electrode between the first insulating film and the second insulating film.

6. The organic light-emitting display apparatus of claim 5, further comprising a cover layer on the second capacitor electrode.

7. The organic light-emitting display apparatus of claim 6, wherein the cover layer includes at least one material selected from Mo, Ti, Cu, and Ag.

8. The organic light-emitting display apparatus of claim 1, wherein the first electrode includes a transparent conductive material.

9. The organic light-emitting display apparatus of claim 8, wherein the transparent conductive material is at least one of indium tin oxide (ITO), indium zinc oxide (IZO), zinc oxide (ZnO), indium oxide (In₂O₃), indium gallium oxide (IGO), and aluminum zinc oxide (AZO).

10. The organic light-emitting display apparatus of claim 1, wherein the first electrode includes a first transparent conductive material layer sequentially stacked on an upper surface of a semi-transparent metal layer.

11. The organic light-emitting display apparatus of claim 10, wherein the first electrode further includes a second transparent conductive material layer under the semi-transparent metal layer.

12. The organic light-emitting display apparatus of claim 10, wherein the semi-transparent metal layer includes Ag.

13. The organic light-emitting display apparatus of claim 1, wherein the intermediate layer is disposed to correspond to the opening, and the opening is formed not to overlap with the TFT but to be separate from the TFT.

14. A method of manufacturing an organic light-emitting display apparatus, the method comprising:
forming a thin-film transistor (TFT) that includes an active layer, a gate electrode, a source electrode, and a drain electrode on a substrate;
forming a first insulating film between the gate electrode and the source electrode and between the gate electrode and the drain electrode;
forming a second insulating film having an opening on the first insulating film;
forming a first electrode between the first insulating film and the second insulating film, such that the first electrode includes a region corresponding to the opening;
forming an intermediate layer having an organic light-emitting layer on the first electrode; and
forming a second electrode on the intermediate layer.

15. The method of claim 14, further comprising forming a protective layer on the first electrode such that the protective layer does not overlap with the opening.

16. The method of claim 15, wherein:
the source electrode, the drain electrode and the protective layer are formed by patterning, and the forming of the protective layer includes:
forming a conductive material layer on the first electrode in a same pattern as the first electrode; and
patterning the protective layer by removing a region of the conductive material layer that overlaps with the opening when the source electrode and the drain electrode are patterned.

17. The method of claim 15, wherein the forming of the protective layer includes:
forming a conductive material layer on the first electrode in a same pattern as the first electrode, using a same material used to form the protective layer;
forming the second insulating film on the conductive material layer to form a resultant structure;
forming a conductive layer for forming the source electrode and the drain electrode on the second insulating film, the conductive layer for forming the source electrode and the drain electrode including a region corresponding to the opening without having a pattern; and
patterning the conductive layer for forming the source electrode and the drain electrode to form the source electrode and the drain electrode,
wherein, in the patterning of the source electrode and the drain electrode, a region of the conductive layer for forming the source electrode and the drain electrode that contacts the opening is removed, and a region of the conductive material layer that overlaps with the opening is removed.

18. The method of claim 17, further comprising washing the resultant structure using a washing solution before the forming of the conductive layer for forming the source electrode and the drain electrode.
